(19) United States
(12) Patent Application Publication
(10) Pub. No.: US 2012/0161361 A1
(43) Pub. Date: Jun. 28, 2012

(54) METHOD FOR POURING RESIN IN A STATOR OF AN ELECTRIC MACHINE, IN PARTICULAR AN AXIAL FLUX ELECTRIC MACHINE

(75) Inventors: Gian Paolo Ghelardi, Novi Ligure (IT); Guido Botto, Sestri Levante (IT); Giuseppe Canepa, Mele (IT)

(73) Assignee: ANSALDO ENERGIA S.P.A, Genova (IT)

(21) Appl. No.: 13/265,771

(22) PCT Filed: Apr. 21, 2010
(86) PCT No.: PCT/IB2010/000890

§ 371 Date: Mar. 15, 2012

(30) Foreign Application Priority Data
Apr. 22, 2009 (IT) T02009A000315

(51) Int. Cl. H01L 21/56; B29C 39/42

(52) U.S. Cl. 264/272.13; 264/102

(57) ABSTRACT

A method for pouring resin in a stator (2) of an electric machine, in particular an axial flux machine, in which a plurality of coils (5) is supported by a magnetic core (4) contained in a container (12), in which resin is poured in order to fill the spaces existing between the various components contained in the container (12). The method comprises the steps of heating a resin (20) until it reaches a pre-set temperature T₁, corresponding to which is a target value of fluidity; supplying in a controlled way an electric current Iₛₜₐₜ to the coils (5) so that the current will flow in the coils (5), which behave as resistors, thus obtaining a heating by the Joule effect of the coils (5) which reach a temperature T₂ that is higher than the temperature T₁ of the resin; mixing the resin with a catalyst and pouring the mixture of resin and catalyst into the container (12) so that the resin fills said spaces; and obtaining complete hardening of the poured resin.

### TECHNICAL FIELD

The present invention relates to a method for pouring resin in a stator of an electric machine, in particular an axial flux machine.

### BACKGROUND ART

Electric machines are known, e.g. axial flux machines, comprising a stator and a rotor provided with a plurality of permanent magnets, angularly movable with respect to the stator upon the rotation of the electric field generated by the stator.

The stator of these machines typically comprises a core (generally toroidal-shaped) made of magnetic material, on which a plurality of coils equally spaced from one another are angularly arranged. The stator further comprises a container accommodating the magnetic core and the coils.

In order to make such a stator, a resin pouring process is carried out, in which a resin is poured into the container; the resin penetrates the spaces between container, core and coils in order to form thermal bridges which extend from the core to the container.

Experience has taught the applicant that making the resin enter small-sized spaces, such as for example the spaces defined in the immediate proximity of the coils of the stator, is difficult.

### DISCLOSURE OF INVENTION

It is the object of the present invention to provide a resin pouring process which facilitates the entrance of resin into even the small-sized spaces.

The previous object is achieved by the present invention as it relates to a method for pouring resin in a stator of an electric machine, in particular an axial flux machine, in which a plurality of coils are supported by a magnetic core contained in a container, in which resin is poured in order to fill the spaces existing between the various components contained in the container, characterized in that it comprises the steps of: heating a resin until it reaches a pre-set temperature T₁ corresponding to which is a target value of fluidity; supplying in a controlled way an electric current Iₛₜₐₜ to the coils so that the current will flow in the coils, which behave as resistors, thus obtaining a heating by the Joule effect of the coils which reach a temperature T₂ that is higher than the temperature T₁ of the resin; and mixing said resin with a catalyst and pouring the mixture of resin and catalyst into the container so that the resin fills said spaces; obtaining complete hardening of the poured resin.

### BRIEF DESCRIPTION OF THE DRAWINGS

The invention will now be disclosed with reference to the accompanying drawings which show a preferred non-limitative embodiment thereof, in which:

FIG. 1 is a perspective view of an initial step of the method according to the present invention; and

FIG. 2 is a final step of the method of the present invention.

### BEST MODE FOR CARRYING OUT THE INVENTION

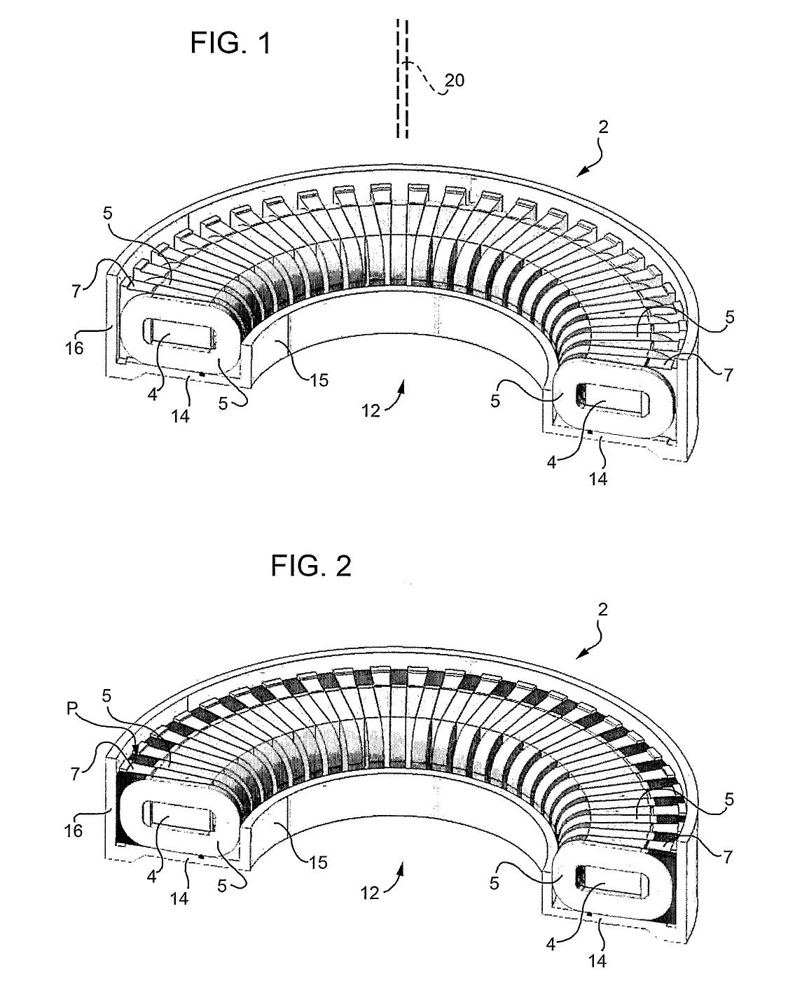

FIG. 1 shows a perspective view of a stator 2 of an electric machine with high power density (not shown), in particular an axial flux motor or an electric generator with axial flux (not shown).

Stator 2 comprises a toroidal core 4 made of magnetic material, which carries a plurality of coils 5 arranged so as to be equally spaced from one another along the whole circumference of the toroidal core 4.

In greater detail, the toroidal core 4 has a substantially rectangular cross-section and is formed by a plurality of metal foils sandwiched onto one other according to known techniques in order to reduce eddy currents.

Each coil 5 has a rectangular periphery in section, with curved sides, and is formed by a metal conductor (normally a flat copper twin cable coated with a layer of insulating paint, not shown) wound about the core 4. The coils 5 are further connected to one another to form first, second and third stator windings of the electric machine, of three-phase type.

Two coils 5 facing each other and an outer wall of core 4 delimit an approximately parallelepiped-shaped space; such a space accommodates a trapezoidal-section, metal tooth 7 which is arranged between the two facing coils 5.

A container 12 defines a toroidal cavity which accommodates stator 2, coils 5 and teeth 7; in particular, such a container has a U-shaped cross section delimited by a flat bottom wall 14 integral with an inner, cylindrical tubular wall 15 and with an outer, cylindrical tubular wall 16. The coils 5 are arranged with a longer side thereof parallel and adjacent to the flat bottom wall 14, and with the teeth 7 facing the outer cylindrical tubular wall 16.

A resin 20 is poured into the container, which insinuates into the spaces between the various teeth 7, between the coils 5 and the teeth 7, between the teeth 7 and the container 12, and between the container 12 and the coils 5.

The resin 20 is of the epoxy type and has high thermal conductivity values (e.g. 1.36 W/m*K of STYCAST FT made by Emerson & Cuming) and high dielectric insulation values (21.7 kV/mm).

A resin pouring method in stator 2 according to the present invention is carried out by introducing the resin 20 into the container 12 in order to fill all the existing spaces and then hardening the resin 20.

The resin pouring method according to the present invention will now be disclosed, which comprises a plurality of steps including:

i) a first step: the resin 20 is heated until it reaches a target value of fluidity—such a first step is conveniently carried out by placing the resin 20 within a container (not shown) and heating the container itself (e.g. in an oven) so that the resin reaches a pre-set temperature T₁, e.g. 60° C., corresponding to which is the target value of fluidity;

ii) a second phase: an electric current is supplied to the coils 5 of stator 2 so that the current flows in the coils 5, which behave as resistors, thus heating by Joule effect the coils 5 themselves—the entity of the supplied current Iₛₜₐₜ, the applied voltage Vₛₜₐₜ and the application time Tₛₜₐₜ of the current are adjusted so that the coils 5 reach a temperature T₂ which is higher than the temperature T₁ of the resin—typically temperature T₂ is of the order of 70-80° C.;

iii) a third phase: the resin is mixed with a catalyst (e.g. for STYCAST FT, CATALYST 11 in a proportion of 4 parts/100 parts of resin) and the mixture of resin 20 and catalyst is poured into the container 12 so that the fluid resin 20 penetrates all the spaces between the various teeth 7, the coils 5 and the teeth 7, between the teeth 7 and the container 12, between the container 12 and the coils 5. The operations of the third step continue until the resin 20 has filled all the aforesaid spaces—during the third step, the electric supply to the coils 5 is maintained.

Thereby, the fluid mixture of resin and catalyst flows on the coils 5, which have a higher temperature than the fluid mixture; such a temperature difference ensures an optimal dispersion of the resin about the coils 5 and ensures the complete filling of all the spaces.

iv) a fourth step: the container 12 is arranged in an autoclave (once the electric supply to coils 5 has been interrupted) in order to considerably reduce the pressure outside the container 12. The pressure is reduced inside the autoclave and brought to less than atmospheric pressure for eliminating air bubbles possibly present in the mixture and generated during the pouring process in step three;

v) a fifth step: complete hardening of the resin. Once container 12 has been extracted from the autoclave, the method consists in waiting for the complete polymerization of the resin in order to obtain the complete hardening of the resin itself. The polymerization of the resin is typically obtained in two steps, e.g. for STYCAST FT, the first step lasting for approximately 2 hours at 100° C., the second for approximately 4 hours at 150° C. The process of the fifth step may be sped up by supplying a controlled current in the coils 5 again, in order to heat the coils 5 and the resin which surrounds them.

vi) a sixth step: known machining operations may be carried out on stator 2, upon complete hardening of resin 20, such as painting and/or mechanical detail machining.

The second step is typically carried out by supplying a current Iₛₜₐₜ varying from 80% of the current rated value (initial value) to 40% of the rated current (end value) of the machine.

The applied voltage Vₛₜₐₜ is preferably in the range from 1 to 2.5 Volts, being 50 Hertz AC.

The application time Tₛₜₐₜ is of the order of 4 minutes.

The third step is typically carried out by apply a current Iₛₜₐₜ having a value of 40% of the rated current of the machine.

The application time Tₛₜₐₜ is of the order of 30 minutes.

Instead, in order to speed up the hardening process, the current supplied during the fifth step takes a value Iₑₛₛ higher than the current Iₛₜₐₜ (40-80% of the rated current) of the second step. The Iₑₛₛ value may be of the order of 40-110% of the rated current value.

The application time (normally in two steps, the first of 120 minutes and the second of 240 minutes) of such a current Iₑₛₛ is also higher than the application time Tₛₜₐₜ in order to ensure the effective completion of the resin hardening process.

The application of the current to the coils 5 may be obtained either directly by connecting a current generator (not shown) to the windings, or indirectly by establishing a magnetic coupling between the coils 5 of stator 2 and further coils (not shown), to which an AC current is supplied. Thereby, the further coils form the primary of a transformer, the secondary of which is formed by the coils 5 of stator 2 which are arranged with the short-circuited windings to close the current on the secondary.

FIG. 2 shows stator 2 at the end of the above-described process.

Such a figure shows the hardened resin 20 arranged in the spaces existing between the adjacent teeth 7 which form thermal bridges P which extend between the coil 4 made of magnetic material and the container 12. These thermal bridges P allow to exchange the heat caused by the losses in the copper conductors of the coils 5 outwards from stator 2, where a fluid cooling system (not shown) may be arranged.

The above-described method allows to effectively provide the aforesaid thermal bridges by virtue of the fluidity increase of the resin during the pouring thereof, obtained by the additional heating supplied by the coils 5 to which an electric current is supplied.

If electric current is further supplied during the fifth step, the complete hardening of the resin is more simple and less time-consuming.

1. A method for pouring resin in a stator (2) of an electric machine, in particular axial flux machine, in which a plurality of coils (5) are supported by a magnetic core (4) contained in a container (12), in which resin is poured in order to fill the spaces existing between the various components contained in the container (12), said method being characterized in that it comprises the steps of:
heating a resin (20) until it reaches a pre-set temperature T₁ corresponding to which is a target value of fluidity;
supplying in a controlled way an electric current Iₛₜₐₜ to the coils (5) in such a way that the current will flow in the coils (5), which behave as resistors, thus obtaining a heating by the Joule effect of the coils (5) themselves, which reach a temperature T₂ that is higher than the temperature T₁ of the resin; and
mixing said resin with a catalyst and pouring the mixture of resin and catalyst inside the container (12) in such a way that the resin fills said spaces;
obtaining complete hardening of the poured resin.

2. The method according to claim 1, wherein the step of obtaining complete hardening of the poured resin comprises the step of supplying a controlled current Iₑₛₛ to said coils (5) in order to obtain heating of the previously poured resin, thus speeding up said hardening step.

3. The method according to claim 2, wherein said controlled current Iₑₛₛ assumes a higher value than said electric current Lₛₜₐₜ.

4. The method according to claim 2, wherein the electric current Iₛₜₐₜ may vary between 40% and 80% of the value of the rated current of the electric machine, and the electric current Iₑₛₛ is in the region of 40-110% of the value of the rated current.

5. The method according to claim 1, wherein the pre-set temperature T₁ is in the region of approximately 60° C., and the temperature T₂ is in the region of 70-80° C.

6. The method according to claim 1, wherein the electric current Iₛₜₐₜ supplied may vary between 80% and 40% of the value of the rated current of the electric machine between an initial step and a final step of supply of the current.

7. The method according to claim 1, wherein a step is provided for elimination of any air bubbles that may be present within the resin and may have been generated during the step of pouring.

8. The method according to claim 7, wherein said step of elimination of air bubbles is obtained by setting said casing in an autoclave and reducing the pressure within the autoclave to bring it below atmospheric pressure.

9. The method according to claim 2, wherein said controlled current Iₑₛₛ is supplied to said coils (5) for an application time Tₛₜₐₜ in the region of 120-240 minutes.

10. The method according to claim 1, wherein said step of supplying an electric current in a controlled way is performed by providing a magnetic coupling between the coils (5) of the stator (2) and at least one further coil to which an a.c. current is supplied; said further coil provides the primary winding of a transformer, the secondary winding of which is provided by the coils (5) of the stator (2).
